(19) United States
(12) Patent Application Publication
(10) Pub. No.: US 2026/0047433 A1
(43) Pub. Date: Feb. 12, 2026

(54) SUBSTRATE PACKAGE

(71) Applicant: Samsung Electronics Co., Ltd., Suwon-si (KR)

(72) Inventors: Hansol YOO, Suwon-si (KR); Jihwan KIM, Suwon-si (KR)

(73) Assignee: Samsung Electronics Co., Ltd., Suwon-si (KR)

(21) Appl. No.: 19/062,382

(22) Filed: Feb. 25, 2025

(30) Foreign Application Priority Data
Aug. 9, 2024 (KR) 10-2024-0106933

(51) Int. Cl. H01L 23/373; H01L 23/31; H01L 23/498; H01L 23/538; H01L 25/065

(52) U.S. Cl. CPC H01L 23/3737; H01L 23/3157; H01L 23/49816; H01L 23/5386; H01L 25/0657; H01L 2225/0651; H01L 2225/06589

(57) ABSTRACT

A semiconductor package may include at least one semiconductor chip including a lower surface, an upper surface and connection pads, the lower surface facing the substrate, the upper surface opposite to the lower surface, the connection pads being on the upper surface; bonding wires electrically connecting the connection pads to the interconnection; an adhesive film having a first surface, a second surface, and fillers, the first surface in contact with the lower surface of the at least one semiconductor chip, the second surface opposite to the first surface, the fillers oriented in a vertical direction between the first surface and the second surface; and connection bumps below the substrate and electrically connected to the interconnection, wherein the adhesive film has stripe patterns defined by the fillers and extend from the first surface to the second surface, and the stripe patterns are spaced apart from each other in a horizontal direction.

### CROSS-REFERENCE TO RELATED APPLICATION(S)

This application claims benefit of priority to Korean Patent Application No. 10-2024-0106933, filed on Aug. 9, 2024 in the Korean Intellectual Property Office, the disclosure of which is incorporated herein by reference in its entirety.

### BACKGROUND

At least some example embodiments relate to a semiconductor package.

In accordance with the implementation of light weightedness and high performance in electronic devices, it may be advantageous to develop relatively highly integrated semiconductor chips. An increase in an amount of heat generated by miniaturized and highly integrated semiconductor chips may be associated with a decrease in the performance of semiconductor chips. Accordingly, a semiconductor packaging technology for effectively dissipating heat generated by semiconductor chips may be desired.

### SUMMARY

An aspect of the present inventive concepts is to provide a semiconductor package having improved heat dissipation characteristics and reliability.

According to some example embodiments of inventive concepts, a semiconductor package may include: a substrate including an interconnection; at least one semiconductor chip having a lower surface, an upper surface, and connection pads, the lower surface facing the substrate, the upper surface opposite to the lower surface, the connection pads being on the upper surface; bonding wires electrically connecting the connection pads to the interconnection; an adhesive film having a first surface and a second surface and including fillers, the first surface in contact with the lower surface of the at least one semiconductor chip, the second surface opposite to the first surface, the fillers oriented in a vertical direction between the first surface and the second surface; and connection bumps below the substrate and electrically connected to the interconnection, wherein the adhesive film has stripe patterns that are defined by the fillers and extend from the first surface to the second surface, and the stripe patterns are spaced apart from each other in a horizontal direction.

According to some example embodiments of inventive concepts, a semiconductor package may include: a substrate including a bonding pad; a plurality of semiconductor chips on the substrate in a vertical direction, each of the plurality of semiconductor chips including a lower surface and an upper surface, the lower surface facing the substrate and the upper surface having connection pads thereon; bonding wires electrically connecting the connection pads of each of the plurality of semiconductor chips to the bonding pad of the substrate; a plurality of adhesive films on the lower surface of each of the plurality of semiconductor chips, each of the plurality of adhesive films including fillers; and a mold at least partially encapsulating the plurality of semiconductor chips and the plurality of adhesive films, wherein at least one surface of an upper surface of the substrate and an upper surface of each of the plurality of semiconductor chips includes a convex portion and a concave portion, at least one adhesive film among the plurality of adhesive films is in contact with the at least one surface, and the fillers within the at least one adhesive film are oriented in the vertical direction on the concave portion of the at least one surface.

According to some example embodiments of inventive concepts, a semiconductor package may include: a substrate including bonding pads; a first semiconductor chip on the substrate and including first connection pads; a first adhesive film between the substrate and the first semiconductor chip and including first fillers; a second semiconductor chip on the first semiconductor chip and including second connection pads; a second adhesive film between the first semiconductor chip and the second semiconductor chip and including second fillers; and bonding wires electrically connecting the first connection pads and the second connection pads to the bonding pads of the substrate, wherein an upper surface of the first semiconductor chip is in in contact with the second adhesive film and includes a first convex portion and a first concave portion, and the second fillers within the second adhesive film are oriented in a vertical direction on the first concave portion.

### BRIEF DESCRIPTION OF DRAWINGS

The above and other aspects, features, and advantages of the present disclosure will be more clearly understood from the following detailed description, taken in conjunction with the accompanying drawings:

FIG. 1 is a perspective view of a semiconductor package according to some example embodiments;

FIGS. 2A to 2D are drawings illustrating adhesive films in example modifications;

FIGS. 3A and 3B are cross-sectional views of a semiconductor package according to some example embodiments;

FIGS. 4A and 4B are partial enlarged views of regions ‘A’ and B′ of FIG. 3A, and FIG. 4C is a drawing for illustrating an example modification of FIG. 4B;

FIGS. 5A and 5B are drawings for illustrating a manufacturing process of a semiconductor package according to some example embodiments;

FIGS. 6A and 6B are drawings for illustrating a manufacturing process of a semiconductor package according to some example embodiments; and

FIGS. 7A and 7B are drawings for illustrating a manufacturing process of a semiconductor package according to some example embodiments.

### DETAILED DESCRIPTION

Hereinafter, with reference to the accompanying drawings, some example embodiments of the present inventive concepts will be described as follows. Unless otherwise specified, in this specification, terms such as ‘upper,’ ‘upper surface,’ ‘lower,’ ‘lower surface,’ ‘side’ and the like are based on the drawings, and actually, may vary depending on the direction in which the components are disposed.

In addition, ordinal numbers such as “first,” “second,” “third,” or the like may be used as labels for specific elements, step portions, directions, or the like to distinguish various elements, step portions, directions, or the like from each other. Terms that are not described using “first,” “second,” or the like in the specification may still be referred to as “first” or “second” in the claims. In addition, terms referenced by a particular ordinal number (e.g., “first” in a particular claim) may be described elsewhere with a different ordinal number (e.g., “second” in the specification or another claim).

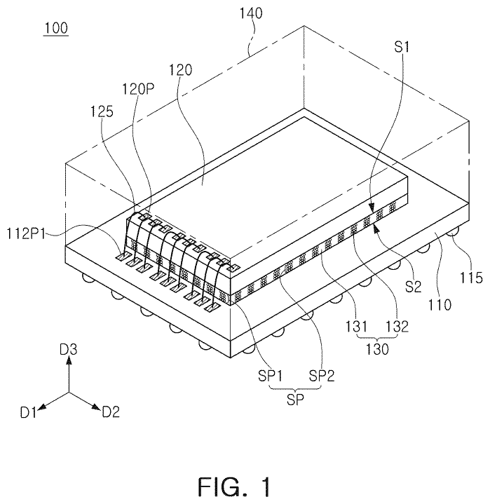

FIG. 1 is a perspective view of a semiconductor package 100 according to some example embodiments.

Referring to FIG. 1, the semiconductor package 100 according to some example embodiments may include a substrate 110, at least one semiconductor chip 120, and at least one adhesive film 130. According to some example embodiments, the semiconductor package 100 may further include a mold 140. According to example embodiments, thermal-conductive fillers 132 within at least one adhesive film 130 may be arranged in a vertical direction D3, accordingly improving the heat dissipation characteristics of the semiconductor package 100. Moreover, as the thermal-conductive fillers 132 may effectively form a heat dissipation path, a content of the fillers 132 in an adhesive resin composition may be reduced and a content of other components may be increased, such that a degree of freedom in designing the properties (e.g., elastic modulus, or the like) of the adhesive resin composition may be improved.

The substrate 110 may be or include a substrate for a semiconductor package such as, for example, a printed circuit board (PCB), a ceramic substrate, a glass substrate, a tape wiring board, and/or the like. For example, the substrate 110 may be or include a double-sided printed circuit board (double-sided PCB) and/or a multilayer printed circuit board (multilayer PCB).

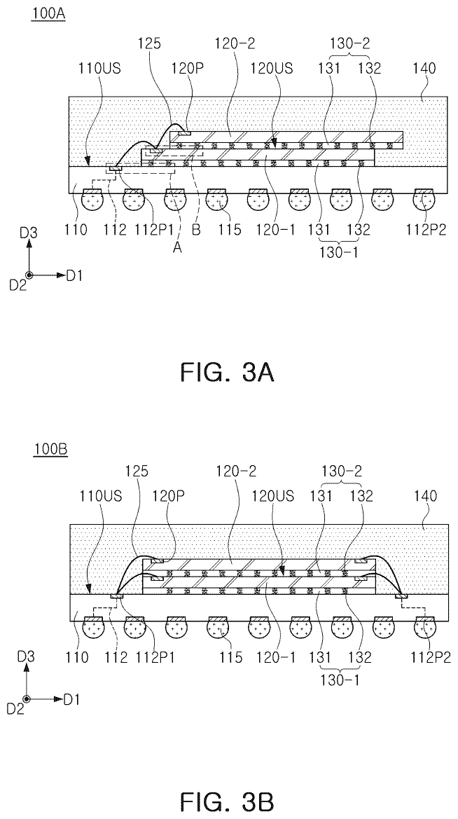

The substrate 110 may include bonding pads 112P1, bump pads 112P2 (for example, see FIG. 3A), and an interconnection 112 (for example, see FIG. 3A) electrically connecting the bonding pads 112P1 and the bump pads 112P2. The bonding pads 112P1 may be disposed on an upper surface of the substrate 110, and the bump pads 112P2 may be disposed on a lower surface of the substrate 110. The bonding pads 112P1 and the bump pads 112P2 may include, for example, at least one metal or an alloy of two or more metals selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), or carbon (C), but example embodiments are not limited thereto.

Connection bumps 115 may be disposed below the bump pads 112P2. The connection bumps 115 may be electrically connected to the semiconductor chip 120 through the interconnection 112. The connection bumps 115 may include, for example, tin (Sn) or an alloy containing tin (Sn) (e.g., Sn—Ag—Cu), but example embodiments are not limited thereto. The connection bumps 115 may be electrically connected to an external device such, for example, as a module substrate, a system board, or the like, but example embodiments are not limited thereto.

At least one semiconductor chip 120 may be attached the substrate 110 such that a lower surface thereof faces the substrate 110. The semiconductor chip 120 may include connection pads 120P disposed on an upper surface thereof. The connection pads 120P may include, for example, one of copper (Cu), nickel (Ni), titanium (Ti), aluminum (Al), and/or an alloy thereof, but example embodiments are not limited thereto. The semiconductor chip 120 may be electrically connected to bonding pads 112P1 of the substrate 110 through bonding wires 125. The bonding wires 125 may connect the connection pads 120P of the semiconductor chip 120 to the bonding pads 112P1 of the substrate 110. The bonding wires 125 may include, for example, gold (Au), silver (Ag), lead (Pb), aluminum (Al), copper (Cu), and/or an alloy thereof, but is not limited thereto. At least one semiconductor chip 120 may be attached or mutually attached to the substrate 110 by an adhesive film 130.

At least one semiconductor chip 120 may include, for example, a non-volatile memory chip such as a flash memory, a phase-change random access memory (PRAM), a magnetoresistive random access memory (MRAM), a ferroelectric random access memory (FeRAM), and/or a resistive random access memory (RRAM), and/or a volatile memory chip such as a dynamic random access memory (DRAM) or a static random access memory (SRAM), but example embodiments are not limited thereto.

At least one adhesive film 130 may be formed using (for example, by using) a film, paste, or the like, including an adhesive resin composition. The adhesive film 130 may be a Die Attach Film (DAF), but an embodiment thereof is not limited thereto. The adhesive film 130 may include an adhesive resin portion 131 and fillers 132.

The adhesive resin portion 131 may also be formed of (for example, include) a synthetic resin, such as, for example, an epoxy resin, a phenolic resin, a melamine resin, a polyester resin, a silicone resin, a urethane resin, a polyamide resin, and/or an acrylic resin, but example embodiments are not limited thereto. The fillers 132 may include at least one of thermally-conductive particles, for example, at least one of alumina (Al₂O₃), aluminum nitride (AlN), boron nitride (BN), magnesium oxide (MgO), zinc oxide (ZnO), or silica (SiO₂), but example embodiments are not limited thereto.

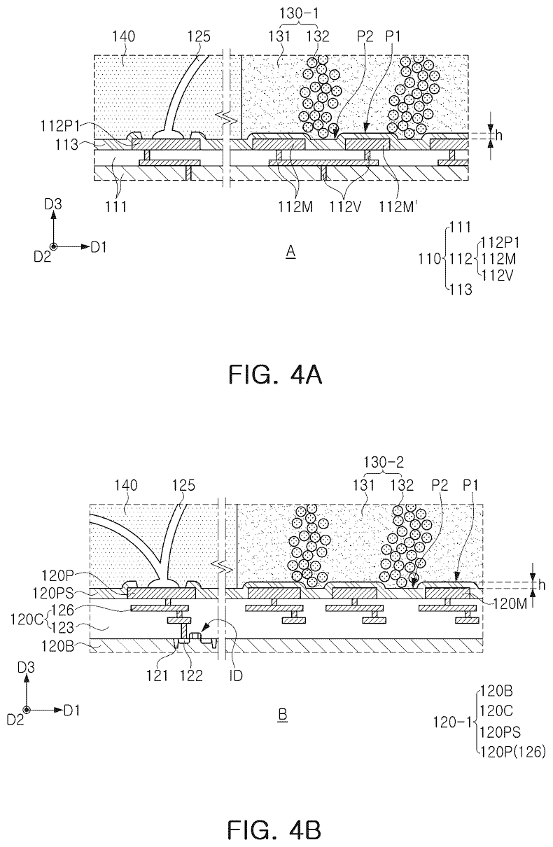

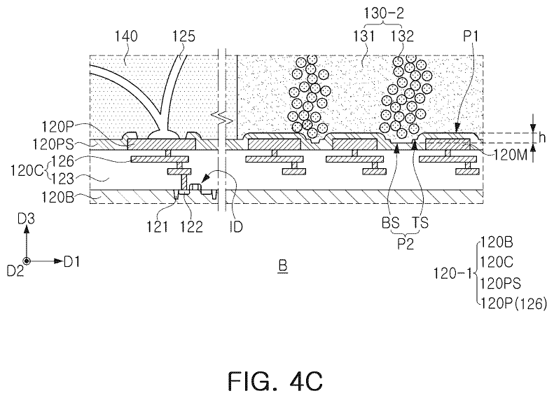

In some example embodiments, the fillers 132 may form stripe patterns SP providing a heat dissipation path (for example, at least one heat dissipation path). The adhesive film 130 may have a first surface S1 in contact with the lower surface of the semiconductor chip 120 and a second surface S2 opposite to the first surface S1. The fillers 132 may be arranged in a vertical direction D3 between the first surface S1 and the second surface S2. At least some of the fillers 132 may contact each other in at least one of the vertical direction D3 and the horizontal direction D1 and D2 (see, for example, FIGS. 4A to 4C). The adhesive film 130 may have stripe patterns SP defined by the fillers 132, and extending (for example, vertically extending) from the first surface S1 to the second surface S2. The stripe patterns SP may be spaced apart from each other in the horizontal direction (D1 and D2). The stripe patterns SP may include first stripe patterns SP1 extending in a first horizontal direction D1 and second stripe patterns SP2 extending in a second horizontal direction D2.

According to some example embodiments, the adhesive film 130 may include fillers 132 arranged in a vertical direction (by, for example, horizontal oscillation) such that heat dissipation performance may be relatively efficiently secured while maintaining a content of the fillers 132 to be about 80 wt % or less, and such that an elastic modulus of the adhesive film 130 may be designed to be about 10 GPa or less. The adhesive film 130 according to example embodiments may have, for example, thermal conductivity of about 1 W/m K or more. In addition, by increasing or allowing the increase of content of other components, a design range of required or desired properties may be secured, or substantially so. For example, by increasing a content of a thermoplastic resin (e.g., acrylic resin), an adhesive resin composition may be more easily produced in the form of a film.

### Adhesive Resin Composition

The adhesive film 130 of the example embodiment may be formed using an adhesive resin composition including a filler 132, a thermoplastic resin, a thermosetting resin, a curing agent, and/or other additives. Hereinafter, an example adhesive resin composition in which a content of fillers 132 is set to about 80 wt % or less, accordingly improving a degree of freedom in controlling a content of other components, is described.

The filler 132 may include, for example, thermally conductive particles such as, for example, alumina (Al₂O₃), aluminum nitride (AlN), boron nitride (BN), magnesium oxide (MgO), zinc oxide (ZnO), silica (Al₂O₃), and/or the like. The filler may be included in an amount of about 80 wt % or less of the total composition, for example, about 60 wt % to about 80 wt %, about 70 wt % to about 80 wt %, or the like. When the filler is included in an amount of less than about 60 wt %, the heat dissipation properties of the adhesive film 130 may deteriorate. When the filler is included in an amount of exceeding about 80 wt %, restrictions may occur in designing the properties of the adhesive film 130.

The thermoplastic resin may include, for example, an acrylic resin. The acrylic resin may include, for example, at least one acrylic monomer selected from the group consisting of, for example, 2-ethylhexyl acrylate, butylacrylate, vinyl acetate, acrylic acid, methyl methacrylate, ethyl methacrylate, butyl methacrylate, methyl acrylate, ethyl acrylate, maleic acid, 2-hydroxypropyl methacrylate, 2-hydroxyethyl methacrylate, 2-hydroxyethyl acrylate, and 2-hydroxypropyl acrylate. The acrylic resin may be included in an amount of about 15 wt % or less of the total composition, for example, in a range of about 1 wt % to about 15 wt %, about 1 wt % to about 10 wt %, about 5 wt % to about 10 wt %, or the like.

The thermosetting resin may include, for example, an epoxy resin. The epoxy resin may include, for example, at least one epoxy component selected from the group consisting of, for example, bisphenol-A type epoxy, bisphenol-F type epoxy, rubber modified epoxy, novolac epoxy, cycloaliphatic epoxy, tetra-functional epoxy, acrylic modified epoxy, coal tar modified epoxy, aliphatic chain modified epoxy, cresol novolac epoxy, polyglycol epoxy, cardanol epoxy, brominated epoxy, and phenoxy epoxy, but example embodiments are not limited thereto. The epoxy resin may be included in an amount of about 10 wt % or more of the total composition, for example, from about 10 wt % to about 30 wt %, from about 10 wt % to about 20 wt %, from about 10 wt % to about 15 wt %, or the like.

The curing agent may include, for example, at least one selected from the group consisting of an acid anhydride curing agent, a cationic curing agent, an imidazole curing agent, a dicyandiamide curing agent, and an amine adduct type curing agent, but example embodiments are not limited thereto. The curing agent may be, for example, included in an amount of about 10 wt % to about 15 wt % of the total composition.

The additives may include, for example, catalysts, foaming agents, adhesion promoters, coupling agents, softeners, and/or the like. The additives may be, for example, included in an amount of greater than 0 wt % and less than or equal to about 1 wt % of the total composition.

The mold 140 may cover or at least partially cover the semiconductor chip 120 on the substrate 110. The mold 140 may include, for example, a thermosetting resin such as an epoxy resin, a thermoplastic resin such as a polyimide, or a resin impregnated with an inorganic filler in these resins, for example, prepreg, Ajinomoto Build-up Film (ABF), Flame Resistant 4 (FR-4), Bismaleimide Triazine (BT), or Epoxy Molding Compound (EMC), but example embodiments are not limited thereto.

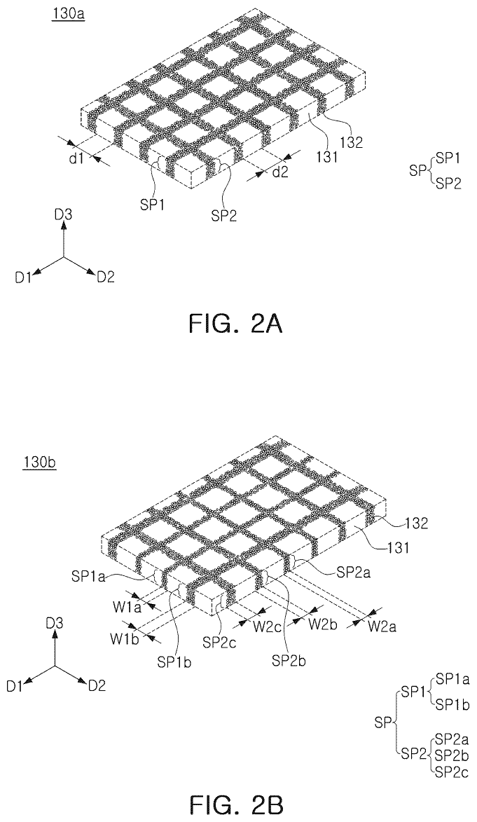

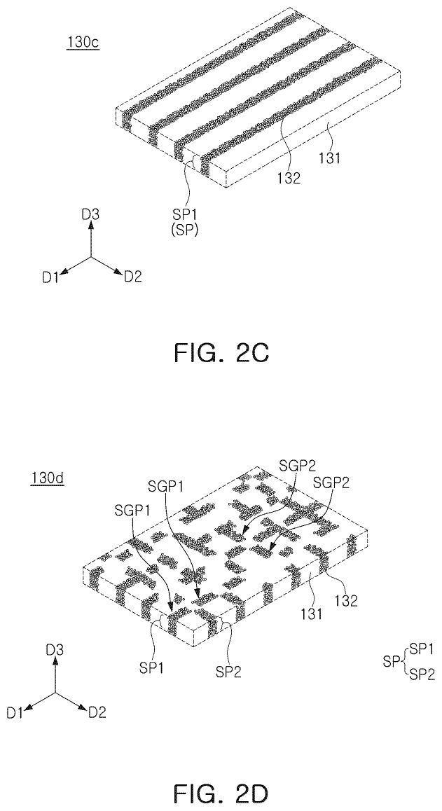

Hereinafter, with reference to FIGS. 2A to 2D, example horizontal arrangement forms of fillers 132 in the adhesive film 130 will be described.

FIGS. 2A to 2D are drawings illustrating adhesive films 130a, 130b, 130c, and 130d according to some example embodiments. FIGS. 2A to 2D may be understood as partial enlarged views respectively illustrating a cross-sectional side view of an adhesive film according to some example embodiments.

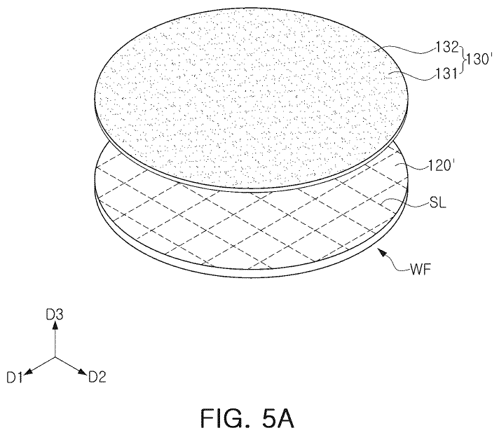

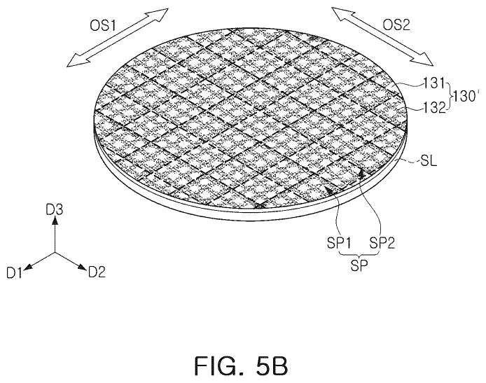

Referring to FIG. 2A, the adhesive film 130a according to some example embodiments may include first stripe patterns SP1 and second stripe patterns SP2. The fillers 132 may be arranged in the vertical direction D3 and horizontal directions D1 and D2, to form first stripe patterns SP1 and second stripe patterns SP2 intersecting each other. The fillers 132 may form first stripe patterns SP1 by oscillation in a second horizontal direction D2, and may form second stripe patterns SP2 by oscillation in a first horizontal direction D1 (see, for example, FIGS. 5A to 7B). Depending on example embodiments, the first horizontal direction D1 and the second horizontal direction D2 may or may not be orthogonal to each other.

The first stripe patterns SP1 may extend in a first horizontal direction D1, respectively, and may be spaced apart from each other in a second horizontal direction D2 intersecting the first horizontal direction D1. Distances (d1) between the first stripe patterns SP1 may, for example, not be constant. The second stripe patterns SP2 may extend in the second horizontal direction D2, respectively, and may be spaced apart from each other in the first horizontal direction D1. Distances (d2) between the second stripe patterns SP2 may, for example, not be constant. The distance (d1) between the first stripe patterns SP1 and the distance (d2) between the second stripe patterns SP2 may be in a range of, for example, about 0.5 mm to about 2 mm, but example embodiments are not limited thereto. The distance (d1) between the first stripe patterns SP1 and the distance (d2) between the second stripe patterns SP2 may be determined according to an amplitude and frequency of horizontal oscillation for orienting the fillers 132. The distance (d1) between the first stripe patterns SP1 and the distance (d2) between the second stripe patterns SP2 may be similar or substantially similar levels. Here, ‘similar levels’ may mean being formed within a range having the same or substantially the same lower and upper limits. At least a portion of the first stripe patterns SP1 may intersect with at least a portion of the second stripe patterns SP2.

Referring to FIG. 2B, the adhesive film 130b according to some example embodiments may include first stripe patterns SP1 and/or second stripe patterns SP2 having different widths. The fillers 132 may form at least a portion of the first stripe patterns SP1a and SP1b having different widths and at least a portion of the second stripe patterns SP2a, SP2b, and SP2c having different widths.

The first stripe patterns SP1 may include 1-1 stripe patterns SP1a and 1-2 stripe patterns SP1b having different widths. A width (W1a) of the 1-1 stripe patterns SP1a in the second horizontal direction D2 may be different from a width (W1b) of the 1-2 stripe patterns SP1b in the second horizontal direction D2. For example, the width (W1a) of the 1-1 stripe patterns SP1a, which is relatively closer to an equilibrium position of the oscillation in the second horizontal direction D2 may be smaller than the width (W1b) of the 1-2 stripe patterns SP1b, which is relatively farther from the equilibrium position thereof.

The second stripe patterns SP2 may include 2-1 stripe patterns SP2a, 2-2 stripe patterns SP2b, and 2-3 stripe patterns SP2c having different widths. A width (W2a) of the 2-1 stripe patterns SP2a in a first horizontal direction D1 may be different from a width (W2b) of the 2-2 stripe patterns SP2b in the first horizontal direction D1 and a width (W2c) of the 2-3 stripe patterns SP2c in the first horizontal direction D1. For example, the width (W2a) of the 2-1 stripe patterns SP2a, which is relatively closer to an equilibrium position of the oscillation in the first horizontal direction D1 may be smaller than the width (W2b) of the 2-2 stripe patterns SP2b, which is relatively farther from the equilibrium position. The width (W2b) of the 2-2 stripe patterns SP2b, which is relatively closer to the equilibrium position of the oscillation in the first horizontal direction D1 may be smaller than the width W2c of the 2-3 stripe patterns SP2c, which is relatively farther from the equilibrium position.

Referring to FIG. 2C, the adhesive film 130c according to example embodiments may include first stripe patterns SP1 or second stripe patterns SP2 extending in one horizontal direction. The fillers 132 may form stripe patterns SP extending in one horizontal direction by, for example, unidirectional oscillation. The stripe patterns SP may include only the first stripe patterns SP1 or the second stripe patterns SP2.

Referring to FIG. 2D, the adhesive film 130d of the example modification may include stripe patterns SP formed by segmented patterns. The fillers 132 may form stripe patterns SP including segmented patterns. Each of the first stripe patterns SP1 may include first segment patterns SGP1 spaced apart from each other in a first horizontal direction D1. Each of the second striped patterns SP2 may include second segment patterns SGP2 spaced apart from each other in a second horizontal direction D2. At least a portion of the first segment patterns SGP1 and at least a portion of the second segment patterns SGP2 may intersect with each other.

As described above, the shape of the stripe patterns SP in the horizontal direction may be variously modified depending on horizontal oscillation conditions during formation.

FIGS. 3A and 3B are cross-sectional views of semiconductor packages 100A and 100B according to some example embodiments.

Referring to FIGS. 3A and 3B, semiconductor packages 100A and 100B according to some example embodiments may include a plurality of semiconductor chips 120-1 and 120-2 stacked on a substrate 110. The semiconductor packages 100A and 100B may include a first semiconductor chip 120-1 disposed on the substrate 110 and at least one second semiconductor chip 120-2 disposed on the first semiconductor chip 120-1. The plurality of semiconductor chips 120-1 and 120-2 may include a greater number of semiconductor chips than those illustrated in the drawings, but example embodiments are not limited thereto. The plurality of semiconductor chips 120-1 and 120-2 may, for example, be stacked to be (for example, such that they are) off-set in the horizontal direction such that that the connection pads 120P of each of the plurality of semiconductor chips is exposed in a vertical direction D3 (see FIG. 3A), but example embodiments are not limited thereto. In some example embodiments, for example, the plurality of semiconductor chips 120-1 and 120-2 may be aligned in the vertical direction D3 so that the respective connection pads 120P overlap (see FIG. 3B).

In addition, the semiconductor packages 100A and 100B may include a plurality of adhesive films 130-1 and 130-2 disposed on a lower surface of each of the plurality of semiconductor chips. The semiconductor packages 100A and 100B may, for example, include a first adhesive film 130-1 disposed between the substrate 110 and the first semiconductor chip 120-1 and a second adhesive film 130-2 disposed between the first semiconductor chip 120-1 and the second semiconductor chip 120-2. The first adhesive film 130-1 and the second adhesive film 130-2 may, for example respectively include fillers 132 having the same, substantially the same, or similar characteristics as those described with reference to FIGS. 1 to 2D.

At least one surface of an upper surface 110US of the substrate 110 and an upper surface of each of the each of the plurality of semiconductor chips 120-1 and 120-2 (e.g., an upper surface 120US of the first semiconductor chip 120-1) may be, for example, a curved surface including a convex portion and a concave portion. At least one of the plurality of adhesive films 130-1 and 130-2 may be in contact with the curved surface, and the fillers 132 may be arranged in a vertical direction D3 on the concave portion of the curved surface.

Hereinafter, with reference to FIGS. 4A to 4C, example vertical arrangement forms of fillers 132 will be described.

FIGS. 4A and 4B are partial enlarged views of regions ‘A’ and ‘B’ of FIG. 3A, respectively, and FIG. 4C is a drawing illustrating example modifications of FIG. 4B.

Referring to FIG. 4A, the fillers 132 may, for example, be arranged in a vertical direction D3 on a concave portion P2 of a substrate 110. The substrate 110 may include an insulating layer 111, an interconnection 112, and a protective layer 113. The insulating layer 111 may include, for example, an insulating resin such as prepreg, ABF, FR-4, BT, or Photoimageable Dielectric (PID), but example embodiments are not limited thereto. The interconnection 112 may include an interconnection pattern 112M and an interconnection via 112V. The interconnection pattern 112M and the interconnection via 112V may include, for example, at least one metal selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), tungsten (W), and iron (Fe), or any alloy comprised of two or more metals thereof, but example embodiments are not limited thereto. The interconnection pattern 112M may include a bonding pad 112P1 and an upper interconnection 112M′ disposed on an uppermost surface of the insulating layer 111. The interconnection via 112V may have, for example, a form of a filled via in which a metal material is filled or at least partially filled inside a via hole or a conformal via in which a metal material is formed along an inner wall of the via hole.

The protective layer 113 may be disposed on the uppermost surface of the insulating layer 111, and may cover or at least partially cover the bonding pad 112P1 and/or the upper interconnection 112M′. The protective layer 113 may have an opening exposing at least a portion of the bonding pad 112P1. The protective layer 113 may be formed using, for example, a solder resist. The protective layer 113 may include a convex portion P1 formed corresponding to the shape of the upper interconnection 112M′. In addition, the protective layer 113 may include a concave portion P2 formed between the upper interconnections 112M′. The protective layer 113 may provide an upper surface of the substrate 110 including a convex portion P1 and a concave portion P2.

The fillers 132 within the first adhesive film 130-1 may be arranged in a vertical direction D3 on the concave portion P2 of the substrate 110. The fillers 132 may form, for example, a stripe or similar pattern on the concave portion P2 of the substrate 110. At least a portion of the fillers 132 arranged on the concave portion P2 may contact each other in at least one of the vertical direction D3 and the horizontal directions D1 and D2.

A diameter of the fillers 132 may be within a range of about 10% to about 70% of a thickness of the first adhesive film 130-1. For example, when the thickness of the first adhesive film 130-1 is about 10 μm or less, the diameter of the fillers may be about 7 μm or less, for example, about within the range of about 1 μm to about 7 μm. When the diameter of the fillers 132 exceeds about 7 μm, the semiconductor chip may be damaged when the fillers 132 are oriented by horizontal oscillation. When the diameter of the fillers 132 is less than about 1 μm, the effect of improving heat dissipation characteristics by the oriented fillers 132 may be reduced.

A step (h) between an upper end of a convex portion P1 and a lower end of a concave portion P2 may be about 1 μm or more, for example, within a range of about 1 μm to about 5 μm, about 1 μm to about 4 μm, about 2 μm to about 3 μm, or the like. When the step (h) between the convex portion P1 and the concave portion P2 is less than about 1 μm, the orientation of the fillers 132 due to horizontal oscillation may not be smoothly or substantially smoothly performed.

Referring to FIG. 4B, fillers 132 may be arranged in a vertical direction D3 on a concave portion P2 of a first semiconductor chip 120-1. The first semiconductor chip 120-1 may include a semiconductor layer 120B, a circuit layer 120C, and a passivation layer 120PS.

The semiconductor layer 120B may be a semiconductor wafer. For example, the semiconductor layer 120B may include a semiconductor element such as, for example, silicon and germanium, or a compound semiconductor such as silicon carbide (SiC), gallium arsenide (GaAs), indium arsenide (InAs), and indium phosphide (InP), but example embodiments are not limited thereto. The semiconductor layer 120B may include a conductive region 122 and an isolation region 121. The conductive region 122 may be, for example, a well doped with impurities, or a structure doped with impurities. The isolation region 121 may be a device isolation structure having a shallow trench isolation (STI) structure, and may include, for example, silicon oxide.

The circuit layer 120C may be disposed on the semiconductor layer 120B on which a conductive region 122 is formed. The circuit layer 120C may include individual devices ID, an interlayer insulating layer 123, and an interconnection structure 126. The individual devices ID may include, for example, FET such as planar FET, FinFET, or the like, a flash memory, a memory device such as flash memory, DRAM, SRAM, EEPROM, PRAM, MRAM, FeRAM, and RRAM, a logic element such as AND, OR, and NOT, and/or various active and/or passive devices such as LSI, CIS, and MEMS.

The interlayer insulating layer 123 may be formed to cover the individual devices ID and the interconnection structure 126, to electrically isolate the individual devices ID. The interlayer insulating layer 123 may include, for example, at least one of a non-metallic inorganic material, for example, silicon oxide (SiO) and silicon nitride (SiN). The interlayer insulating layer 123 may include, for example, Flowable Oxide (FOX), Tonen SilaZen (TOSZ), Undoped Silicate Glass (USG), Borosilicate Glass (BSG), PhosphoSilicate Glass (PSG), BoroPhosphoSilicate Glass (BPSG), Plasma Enhanced Tetra Ethyl Ortho Silicate (PETEOS), Fluoride Silicate Glass (FSG), High Density Plasma (HDP) oxide, Plasma Enhanced Oxide (PEOX), Flowable CVD (FCVD) oxide, and/or a combination thereof.

At least a portion of the interlayer insulating layer 123 surrounding the interconnection structure 126 may be comprised of a low dielectric layer. The interlayer insulating layer 123 may be formed using, for example, a chemical vapor deposition (CVD) process, a flowable CVD process, or a spin coating process, but example embodiments are not limited thereto. The interconnection structure 126 may be disposed within the interlayer insulating layer 123. The interconnection structure 126 may be formed as a multilayer structure including a plurality of interconnection patterns formed of, for example, aluminum (Al), gold (Au), cobalt (Co), copper (Cu), nickel (Ni), lead (Pb), tantalum (Ta), tellurium (Te), titanium (Ti), tungsten (W), or a combination thereof and a plurality of vias. A barrier film (not shown) including, for example, titanium (Ti), titanium nitride (TiN), tantalum (Ta), or tantalum nitride (TaN) may be disposed between the interconnection pattern and/or the interlayer insulating layer 123. The interconnection structure 126 may be electrically connected to the conductive region 122 and/or individual devices ID. The interconnection structure 126 may include a connection pad 120P and upper patterns 120M. The connection pad 120P may include, for example, aluminum (Al) or an aluminum (Al) alloy, but is not limited thereto.

The passivation layer 120PS may be disposed on an uppermost surface of the interlayer insulating layer 123, and cover a connection pad 120P and upper patterns 120M. The passivation layer 120PS may have an opening exposing at least a portion of the connection pad 120P. The passivation layer 120PS may include a single-layer or multilayer insulating film. For example, the passivation layer 120PS may include an oxide film and/or a nitride film, but example embodiments are not limited thereto. In some example embodiments, the passivation layer 120PS may include a photosensitive polyimide (PSPI). The passivation layer 120PS may include a convex portion P1 formed corresponding to the shape of the upper patterns 120M, and a concave portion P2 formed between the upper patterns 120M. The passivation layer 120PS may provide an upper surface of a first semiconductor chip 120-1 including the convex portion P1 and the concave portion P2.

The fillers 132 within the second adhesive film 130-2 may be arranged in a vertical direction D3 on a concave portion P2 of the first semiconductor chip 120-1. The fillers 132 may form a stripe pattern on the concave portion P2 of the first semiconductor chip 120-1. At least a portion of the fillers 132 arranged on the concave portion P2 may be in contact with each other in at least one of the vertical direction D3 and the horizontal direction D1 and D2.

A diameter of the fillers 132 may be within a range of about 10% to about 70% of a thickness of the second adhesive film 130-2. For example, when the thickness of the second adhesive film 130-2 is about 10 μm, the diameter of the fillers 132 may be about 7 μm or less, for example, within a range of about 1 μm to about 7 μm. When the diameter of the fillers 132 exceeds about 7 μm, the semiconductor chip may be damaged when the fillers 132 are oriented by horizontal oscillation. When the diameter of the fillers 132 is less than about 1 μm, the effect of improving the heat dissipation characteristics by the oriented fillers 132 may be reduced.

A step (h) between an upper end of a convex portion P1 and a lower end of a concave portion P2 may be about 1 μm or more, for example, within a range of about 1 μm to about 5 μm, about 1 μm to about 4 μm, about 2 μm to about 3 μm, or the like. When the step (h) between the convex portion P1 and the concave portion P2 is less than about 1 μm, the orientation the fillers 132 due to horizontal oscillation may not be smoothly performed.

Referring to FIG. 4C, the concave portion P2 of the first semiconductor chip 120-1 may have a bottom surface BS and a step surface TS, and the fillers 132 may be arranged in a vertical direction D3 on the bottom surface BS and the step surface TS. A step (h) between an upper end of a convex portion P1 and a lower end of a concave portion P2 may be about 1 μm or more, for example, within a range of about 1 μm to about 5 μm, about 1 μm to about 4 μm, about 2 μm to about 3 μm, or the like. A step structure of the concave portion P2 can facilitate smoother orientation of the fillers 132.

As described above, a location at which a stripe pattern is formed by the fillers 132 may depend on the curvature of the lower portion thereof, but example embodiments are not limited thereto. In some example embodiments, the fillers 132 may form a stripe pattern at a location that is independent of the shape of the lower portion thereof (see the examples of FIGS. 5A and 5B).

FIGS. 5A and 5B are drawings for illustrating a manufacturing process of a semiconductor package according to some example embodiments.

Referring to FIG. 5A, a semiconductor wafer WF and a pre-adhesive film 130′ may be prepared. The semiconductor wafer WF may include pre-semiconductor chips 120′ separated by scribe lanes SL. The preliminary adhesive film 130′ may be attached to a back side of the semiconductor wafer WF. For example, the preliminary adhesive film 130′ may be attached to an inactive surface of the preliminary semiconductor chips 120′ on which connection pads are not formed. In the drawing, it can be understood that a circuit layer for the preliminary semiconductor chips 120′ is formed on a lower surface of the semiconductor wafer WF.

The pre-adhesive film 130′ may be formed using, for example, the above-described adhesive resin composition. The pre-adhesive film 130′ may include an adhesive resin portion 131 and fillers 132. The fillers 132 may be dispersed within the adhesive resin portion 131. The fillers 132 may be included in the pre-adhesive film 130′ in an amount of about 80 wt % or less, but example embodiments are not limited thereto. Viscosity of the pre-adhesive film 130′ may be about 3000 Pas (120° C.) or less, for example, in a range of about 100 Pa·s to about 3000 Pa·s, about 300 Pa·s to about 3000 Pa·s, about 500 Pa·s to about 3000 Pa·s, or the like. When the viscosity of the pre-adhesive film 130′ exceeds about 3000 Pa's (120° C.), the arrangement of the fillers 132 may not be smooth or substantially smooth. A thickness of the pre-adhesive film 130′ may be about 20 μm or less, but example embodiments are not limited thereto.

Referring to FIG. 5B, a pre-adhesive film 130′ having stripe patterns SP may be formed by applying horizontal oscillation to a semiconductor wafer WF. The stripe patterns SP may be formed by fillers 132 oriented in a vertical direction D3 and horizontal directions D1 and D2. The fillers 132 may be oriented in a specific direction by horizontal oscillations OS1 and OS2. The horizontal oscillations OS1 and OS2 may be, for example, applied with an amplitude of about 500 μm or less and a frequency of about 40,000 Hz or less. The fillers 132 may form stripe patterns SP1 oriented in a first horizontal direction D1 and a vertical direction D3 by the second horizontal oscillation OS2. In addition, the fillers 132 may form second stripe patterns SP2 oriented in a second horizontal direction D2 and a vertical direction D3 by the first horizontal oscillation OS1. Thereafter, the semiconductor wafer WF and the pre-adhesive film 130′ may be cut along scribe lane(s) SL, to separate the semiconductor chips 120 to which the adhesive film 130 is attached (see FIG. 1).

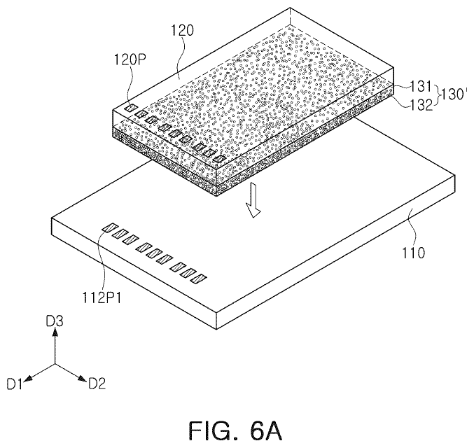

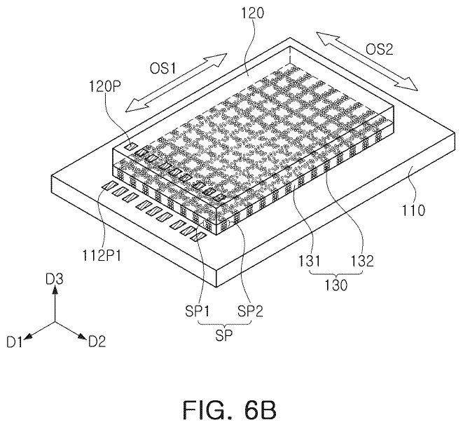

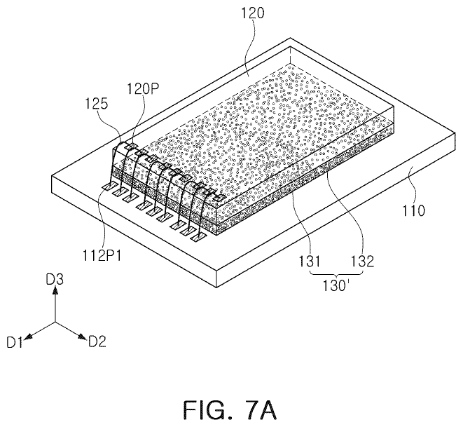

FIGS. 6A and 6B are drawings for illustrating a manufacturing process of a semiconductor package according to some example embodiments.

Referring to FIG. 6A, a semiconductor chip 120 with a pre-adhesive film 130′ attached thereto may be disposed on a substrate 110. The substrate 110 may be a strip substrate including unit substrates respectively including corresponding to a plurality of semiconductor chips 120. The semiconductor chip 120 may be attached to an upper surface of the substrate 110 by a pre-adhesive film 130′. The pre-adhesive film 130′ may have the same, substantially the same, or similar characteristics (for example, thickness, viscosity, and/or the like) as those described with reference to FIG. 5A. Fillers 132 may be included in the pre-adhesive film 130′ in an amount of about 80 wt % or less and may be dispersed in an adhesive resin portion 131, but example embodiments are not limited thereto. The semiconductor chip 120 and the pre-adhesive film 130 illustrated in FIG. 6A may be understood as a semiconductor wafer diced without horizontal oscillation, unlike those in FIG. 5B.

Referring to FIG. 6B, by applying horizontal oscillation a semiconductor chip 120 attached to a substrate 110, an adhesive film 130 having stripe patterns SP may be formed. The stripe patterns SP may be formed by fillers 132 oriented in a vertical direction D3 and horizontal directions D1 and D2. Horizontal oscillations OS1 and OS2 may be applied with an amplitude of about 500 μm or less and a frequency of about 40,000 Hz or less. For example, the fillers 132 may form first stripe patterns SP1 by the second horizontal oscillation OS2. In addition, or alternatively, the fillers 132 may form second stripe patterns SP2 by the first horizontal oscillation OS1. According to some example embodiments, a plurality of semiconductor chips 120 may be stacked on the substrate 110 in a vertical direction D3, and an orientation process of the fillers 132 may be applied to each of the plurality of semiconductor chips 120. Thereafter, a wire bonding process, a molding process, and the like may be performed to manufacture a semiconductor package.

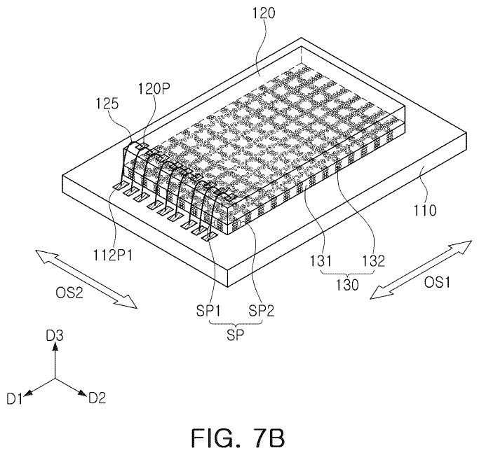

FIGS. 7A and 7B are drawings for illustrating a manufacturing process of a semiconductor package according to some example embodiments.

Referring to FIG. 7A, bonding wires 125 connecting a semiconductor chip 120 and a substrate 110 may be formed. The bonding wires 125 may electrically connect connection pads 120P and bonding pads 112P1. The semiconductor chip 120 may be attached to an upper surface of the substrate 110 by a pre-adhesive film 130′. The pre-adhesive film 130′ may be understood to have the same, substantially the same, or similar characteristics (for example, thickness, viscosity, and/or the like), as those described with reference to FIG. 5A. Fillers 132 may be included in the pre-adhesive film 130′ in an amount of about 80 wt % or less. Depending on example embodiments, a plurality of semiconductor chips 120 may be stacked on the substrate in a vertical direction D3, and bonding wires 125 connecting the connection pads 120P of each of the plurality of semiconductor chips 120 may be formed.

Referring to FIG. 7B, by applying horizontal oscillation to the substrate 110 or a substrate strip, an adhesive film 130 having stripe patterns SP may be formed. The stripe patterns SP may be formed by fillers 132 oriented in the vertical direction D3 and horizontal directions D1 and D2. Horizontal oscillations OS1 and OS2 may be applied with an amplitude of about 500 μm or less and a frequency of about 40,000 Hz or less. In the present example embodiments, horizontal oscillations OS1 and OS2 with a relatively lower frequency than that in the embodiments of FIGS. 5b and 6b may be applied, in order to reduce or prevent damage to the bonding wires 125. For example, the fillers 132 may form first stripe patterns SP1 by the second horizontal oscillation OS2. In addition, the fillers 132 may form second stripe patterns SP2 by the first horizontal oscillation OS1. Thereafter, a molding process, or the like, may be performed to manufacture a semiconductor package.

As set forth above, according to some example embodiments of the present inventive concepts, a semiconductor package having improved heat dissipation characteristics and reliability may be provided by arranging fillers within an adhesive film in a vertical direction.

The various and advantageous advantages and effects of the present inventive concepts are not limited to the above description, and may be more easily understood in the course of describing the specific embodiments of the present inventive concepts. While example embodiments have been shown and described above, it will be apparent to those ordinarily skilled in the art that modifications and variations could be made without departing from the spirit and scope of the present inventive concepts as in the appended claims.

Singular expressions may include plural expressions unless the context clearly indicates otherwise. Terms, such as “include” or “has” may be interpreted as adding features, numbers, steps, operations, components, parts, or combinations thereof described in the specification.

It will be understood that when an element or layer is referred to as being “on”, “connected to”, “coupled to”, “attached to”, or “in contact with” another element or layer, it can be directly on, connected to, coupled to, attached to, or in contact with the other element or layer, or intervening elements or layers may be present. In contrast, when an element is referred to as being “directly on”, “directly connected to”, “directly coupled to”, “directly attached to”, or “in direct contact with” another element or layer, there are no intervening elements or layers present. As used herein, the term “and/or” includes any and all combinations of one or more of the associated listed items.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

Spatially relative terms (e.g., “beneath,” “below,” “lower,” “above,” “upper,” and the like) may be used herein for ease of description to describe one element or feature's relationship to another element(s) or feature(s) as illustrated in the figures. It should be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other at other orientations) and the spatially relative descriptors used herein interpreted accordingly.

What is claimed is:

1. A semiconductor package, comprising:
a substrate including an interconnection;
at least one semiconductor chip having a lower surface, an upper surface and connection pads, the lower surface facing the substrate, the upper surface opposite to the lower surface, the connection pads being on the upper surface;
bonding wires electrically connecting the connection pads to the interconnection;
an adhesive film having a first surface, a second surface and fillers, the first surface in contact with the lower surface of the at least one semiconductor chip, the second surface opposite to the first surface, the fillers oriented in a vertical direction between the first surface and the second surface; and
connection bumps below the substrate and electrically connected to the interconnection,
wherein the adhesive film has stripe patterns that are defined by the fillers and extend from the first surface to the second surface, and
the stripe patterns are spaced apart from each other in a horizontal direction.

2. The semiconductor package of claim 1, wherein
the horizontal direction includes a first horizontal direction and a second horizontal direction that are perpendicular to each other,
the stripe patterns include first stripe patterns extending in the first horizontal direction and second stripe patterns extending in the second horizontal direction,
the first stripe patterns are spaced apart from each other in the second horizontal direction, and
the second stripe patterns are spaced apart from each other in the first horizontal direction.

3. The semiconductor package of claim 2, wherein at least a portion of the first stripe patterns and at least a portion of the second stripe patterns intersect with each other.

4. The semiconductor package of claim 2, wherein
the first stripe patterns include first segment patterns that are spaced apart from each other in the first horizontal direction, and
the second stripe patterns include second segment patterns that are spaced apart from each other in the second horizontal direction.

5. The semiconductor package of claim 1, wherein a width of at least a portion of the stripe patterns in the horizontal direction are different from each other.

6. The semiconductor package of claim 1, wherein
the horizontal direction includes a first horizontal direction and a second horizontal direction that are perpendicular to each other, and
the stripe patterns extend in the first horizontal direction or the second horizontal direction.

7. The semiconductor package of claim 1, wherein at least a portion of the fillers included in each of the stripe patterns are in contact with each other in at least one of the vertical direction or the horizontal direction.

8. The semiconductor package of claim 1, wherein a content of the fillers within the adhesive film is 80 wt % or less.

9. The semiconductor package of claim 1, wherein the fillers include at least one of alumina (Al₂O₃), aluminum nitride (AlN), boron nitride (BN), magnesium oxide (MgO), zinc oxide (ZnO), or silica (SiO₂).

10. A semiconductor package, comprising:
a substrate including a bonding pad;
a plurality of semiconductor chips on the substrate in a vertical direction, each of the plurality of semiconductor chips including a lower surface and an upper surface, the lower surface facing the substrate and the upper surface having connection pads thereon;
bonding wires electrically connecting the connection pads of each of the plurality of semiconductor chips to the bonding pad of the substrate;
a plurality of adhesive films on the lower surface of each of the plurality of semiconductor chips, each of the plurality of adhesive films including fillers; and
a mold at least partially encapsulating the plurality of semiconductor chips and the plurality of adhesive films,
wherein at least one surface of an upper surface of the substrate and an upper surface of each of the plurality of semiconductor chips includes a convex portion and a concave portion,
at least one adhesive film among the plurality of adhesive films is in contact with the at least one surface, and
the fillers within the at least one adhesive film are oriented in the vertical direction on the concave portion of the at least one surface.

11. The semiconductor package of claim 10, wherein a step between an upper end of the convex portion and a lower end of the concave portion is 3 μm or more.

12. The semiconductor package of claim 10, wherein the plurality of semiconductor chips are off-set in a horizontal direction such that the connection pads of each of the plurality of semiconductor chips are exposed in the vertical direction.

13. The semiconductor package of claim 10, wherein the plurality of semiconductor chips are aligned in the vertical direction such that the connection pads of each of the plurality of semiconductor chips at least partially overlap with each other.

14. A semiconductor package, comprising:
a substrate including bonding pads;
a first semiconductor chip on the substrate and including first connection pads;
a first adhesive film between the substrate and the first semiconductor chip and including first fillers;
a second semiconductor chip on the first semiconductor chip and including second connection pads;
a second adhesive film between the first semiconductor chip and the second semiconductor chip and including second fillers; and
bonding wires electrically connecting the first connection pads and the second connection pads to the bonding pads of the substrate,
wherein an upper surface of the first semiconductor chip is in in contact with the second adhesive film and includes a first convex portion and a first concave portion, and
the second fillers within the second adhesive film are oriented in a vertical direction on the first concave portion.

15. The semiconductor package of claim 14, wherein the first semiconductor chip further comprises:
upper patterns spaced apart from the first connection pads, and
a passivation layer at least partially covering the upper patterns and defining the first convex portion and the first concave portion.

16. The semiconductor package of claim 15, wherein the first concave portion is located between the upper patterns.

17. The semiconductor package of claim 14, wherein
the upper surface of the substrate is in contact with the first adhesive film and includes a second convex portion and a second concave portion, and
the first fillers within the first adhesive film are oriented in a vertical direction on the second concave portion.

18. The semiconductor package of claim 17, wherein the substrate further includes:
upper interconnections spaced apart from the bonding pads, and
a protective layer covering the upper interconnections and defining the second convex portion and the second concave portion,
wherein the second concave portion is located between the upper interconnections.

19. The semiconductor package of claim 14, wherein a diameter of the first fillers and the second fillers is 7 μm or less.

20. The semiconductor package of claim 14, wherein a thickness of each of the first adhesive film and the second adhesive film is 20 μm or less.
